(19) United States
(12) Patent Application Publication
(10) Pub. No.: US 2023/0129154 A1
(43) Pub. Date: Apr. 27, 2023

(54) SOLAR CELL MODULE

(71) Applicants: Kabushiki Kaisha Toshiba, Tokyo (JP); Toshiba Energy Systems & Solutions Corporation, Kawasaki-shi (JP)

(72) Inventors: Takeshi GOTANDA, Yokohama (JP); Katsuya YAMASHITA, Yokohama (JP); Haruki OHNISHI, Yokohama (JP); Yutaka SAITA, Yokohama (JP); Tomohiro TOBARI, Yokohama (JP)

(73) Assignees: Kabushiki Kaisha Toshiba, Tokyo (JP); Toshiba Energy Systems & Solutions Corporation, Kawasaki-shi (JP)

(21) Appl. No.: 18/048,893

(22) Filed: Oct. 24, 2022

(30) Foreign Application Priority Data
Oct. 26, 2021 (JP) 2021-174342

(51) Int. Cl. H01G 9/20

(52) U.S. Cl. CPC H01G 9/2081

(57) ABSTRACT

A solar cell module of the embodiment includes a first solar cell element and a second solar cell element disposed to be aligned, a connection member, and a shield member. The connection member electrically connects a first electrode of the first solar cell element and a second electrode of the second solar cell element. The first solar cell element and the second solar cell element each include a first cell containing a perovskite semiconductor and a second cell containing silicon. The first electrode is disposed at an end portion in a first direction in which the first cell is disposed in a thickness direction. The second electrode is disposed at an end portion in a second direction in which the second cell is disposed in the thickness direction. The shield member is made of an electrically insulating material and is disposed between an end portion of the first electrode of the first solar cell element on the second solar cell element side and the connection member.

### CROSS-REFERENCE TO RELATED APPLICATIONS

This application is based upon and claims the benefit of priority from Japanese Patent Application No. 2021-174342, filed on Oct. 26, 2021; the entire contents of which are incorporated herein by reference.

### FIELD

Embodiments described herein relate generally to a solar cell module.

### BACKGROUND

A solar cell module includes a plurality of tandem-type solar cell elements. A tandem-type solar cell element includes a top cell containing a perovskite semiconductor and a bottom cell containing silicon. The top cell and the bottom cell are electrically connected in series. The solar cell module includes a first solar cell element and a second solar cell element disposed to be aligned as a plurality of solar cell elements. The solar cell module includes a connection member that electrically connects a first electrode of the first solar cell element and a second electrode of the second solar cell element. Deterioration in power generation performance is required to be curbed in the solar cell module.

### BRIEF DESCRIPTION OF THE DRAWINGS

FIG. 1 is a plan view of a solar cell module.

FIG. 2 is a cross-sectional view of a solar cell element along line II-II of FIG. 1.

FIG. 3 is a cross-sectional view along line of FIG. 1.

FIG. 4 is an enlarged view around a shield member.

### DETAILED DESCRIPTION

A solar cell module of an embodiment includes a first solar cell element and a second solar cell element disposed to be aligned, a connection member, and a shield member. The connection member electrically connects a first electrode of the first solar cell element and a second electrode of the second solar cell element. The first solar cell element and the second solar cell element each include a first cell containing a perovskite semiconductor and a second cell containing silicon. The first cell and the second cell are disposed to be aligned in a thickness direction of the first solar cell element and the second solar cell element to be electrically connected in series. The first electrode is disposed at an end portion in a first direction in which the first cell is disposed in the thickness direction. The second electrode is disposed at an end portion in a second direction in which the second cell is disposed in the thickness direction. The shield member is made of an electrically insulating material and is disposed between an end portion of the first electrode of the first solar cell element on the second solar cell element side and the connection member.

Hereinafter, a solar cell module of an embodiment will be described with reference to the drawings.

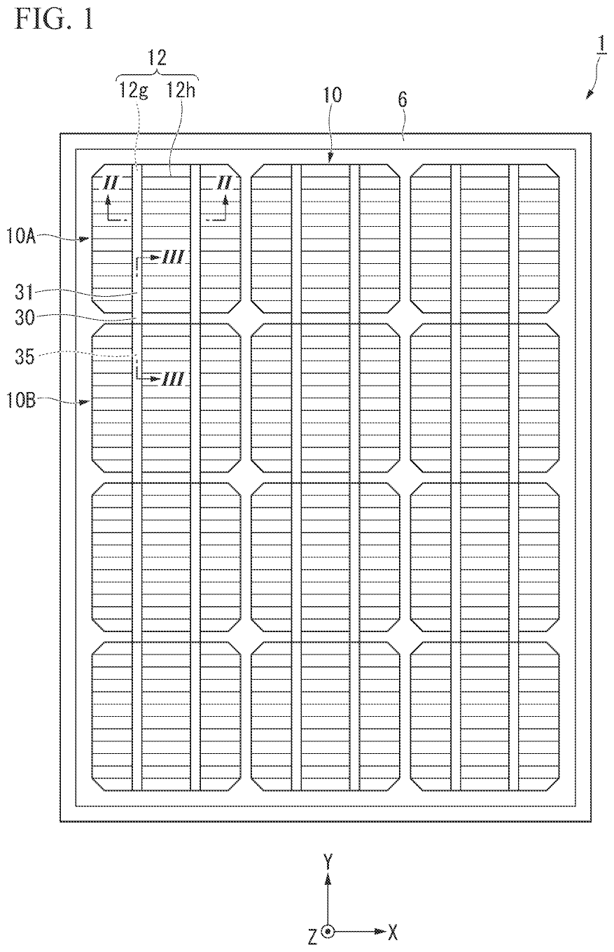

FIG. 1 is a plan view of a solar cell module. In the present application, a Z direction is a thickness direction of a solar cell module 1. An X direction and a Y direction are directions perpendicular to the Z direction and are perpendicular to each other. The solar cell module 1 includes a plurality of tandem-type solar cell elements 10. The plurality of solar cell elements 10 are disposed to be aligned in the X direction and Y direction.

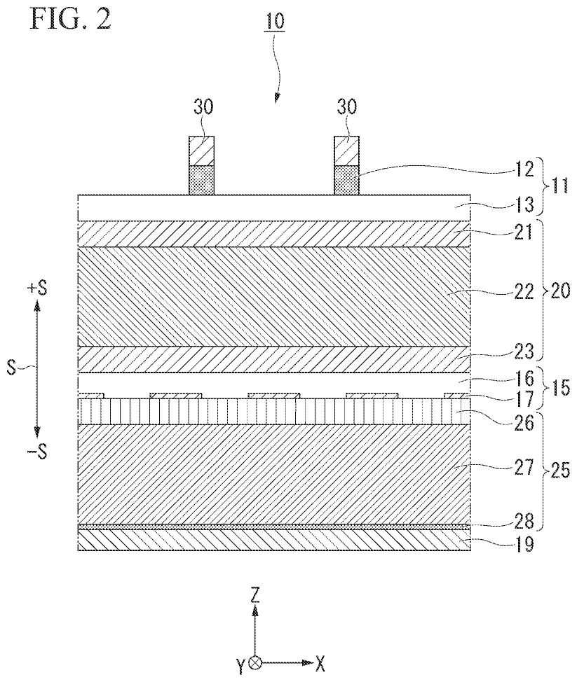

FIG. 2 is a cross-sectional view of the solar cell element along line II-II of FIG. 1. The solar cell element 10 includes a top cell 20 and a bottom cell 25 disposed to be aligned in the thickness direction. In the present application, an S direction is a thickness direction of the solar cell element 10. A +S direction (first direction) is a direction in which the top cell 20 is disposed, and a −S direction (second direction) is a direction in which the bottom cell 25 is disposed.

The solar cell element 10 includes a first electrode 11, the top cell (first cell) 20, an intermediate electrode 15, the bottom cell (second cell) 25, and a second electrode 19 in that order from a side in the +S direction to a side in the −S direction.

The top cell 20 includes a first photoactive layer 22 containing a perovskite semiconductor. The bottom cell 25 includes a second photoactive layer 27 containing silicon. The photoactive layers 22 and 27 are excited by incident light to generate electrons or holes. The solar cell element 10 is a tandem-type solar cell element 10 in which the top cell 20 and the bottom cell 25 are connected in series by the intermediate electrode 15. The electrons or holes generated in the solar cell element 10 are extracted from the first electrode 11 or the second electrode 19.

The top cell 20 includes a first buffer layer 21, a first photoactive layer 22, and a second buffer layer 23 in that order from a side in the +S direction to a side in the −S direction.

The first photoactive layer 22 has a perovskite structure in at least a part thereof. The perovskite structure is one of crystal structures and has the same crystal structure as that of perovskite. Typically, the perovskite structure is formed of ions A, B, and X, and is represented by the following general expression (1).

ABX₃ (1)

A primary ammonium ion such as CH₃NH₃⁺ can be utilized for A. A divalent metal ion such as Pb²⁺ or Sn²⁺ can be utilized for B. A halogen ion such as Cl⁻, Br⁻, or I⁻ can be utilized for X.

This crystal structure has a unit lattice such as a cubic crystal, a tetragonal crystal or an orthorhombic crystal, or the like. In this crystal structure, A is disposed at each vertex, B is disposed at a body center, and X is disposed at each face center of the cubic crystal with the body center as a center. In this crystal structure, an octahedron formed of one B and six X's contained in the unit lattice is easily distorted by an interaction with A, and undergoes a phase transition to a symmetrical crystal. It is presumed that this phase transition dramatically changes physical properties of the crystal, electrons or holes are emitted outside of the crystal, and thereby electricity is generated.

A thickness of the first photoactive layer 22 is preferably 30 to 1000 nm, and more preferably 60 to 600 nm. The first photoactive layer 22 is preferably formed by a coating method.

One of the first buffer layer 21 and the second buffer layer 23 functions as a hole transport layer, and the other thereof functions as an electron transport layer. A halogen compound such as LiF or a metal oxide such as titanium oxide can be utilized as the electron transport layer. A p-type organic semiconductor containing a copolymer consisting of a donor unit and an acceptor unit can be utilized as the hole transport layer. As such materials, polythiophene, derivatives thereof, and the like are preferable. Since the second buffer layer 23 serves as an underlayer for the first photoactive layer 22, it is preferable that a surface of the second buffer layer 23 be substantially a smooth surface. The top cell 20 may not include either or both of the first buffer layer 21 and the second buffer layer 23.

The bottom cell 25 includes a first doped layer 26, the second photoactive layer 27, and a second doped layer 28 in that order from a side in the +S direction to a side in the −S direction.

The second photoactive layer 27 contains silicon. Specifically, crystalline silicon including single crystal silicon, polycrystalline silicon, heterojunction silicon, and the like, or thin film silicon including amorphous silicon can be exemplified. The silicon may be a thin film cut out from a silicon wafer. As the silicon wafer, an n-type silicon crystal doped with phosphorus or the like, or a p-type silicon crystal doped with boron or the like can be utilized. A thickness of the second photoactive layer 27 is preferably 100 to 300 μm.

As the first doped layer 26 and the second doped layer 28, an n-type layer, a p-type layer, a p⁺-type layer, a p⁺⁺-type layer, or the like can be utilized according to characteristics of the second photoactive layer 27. For example, combinations of these layers are employed according to an objective such as improving a carrier collection efficiency. For example, when p-type silicon is used as the second photoactive layer 27, a combination of a phosphorus-doped silicon layer (n layer) as the first doped layer 26 and a p⁺ layer as the second doped layer 28 can be employed.

The first electrode 11 is disposed at an end portion of the solar cell element 10 in the +S direction. The first electrode 11 includes a metal electrode 12 and a first transparent electrode 13 in that order from a side in the +S direction to a side in the −S direction.

The metal electrode 12 is formed of a conductive material such as copper. A thickness of the metal electrode 12 is preferably 30 to 300 nm.

As illustrated in FIG. 1, the metal electrode 12 has a thick line part 12g and a thin line part 12h. The thick line part 12g extends linearly. In the example of FIG. 1, two thick line parts 12g extending in the Y direction are disposed with a gap therebetween in the X direction. The solar cell element 10 is divided into approximately three equal sections in the X direction by the two thick line parts 12g. A width of the thick line part 12g is preferably 10 to 1000 μm. A width of the thin line part 12h is smaller than that of the thick line part 12g. The thin line part 12h extends linearly. In the example of FIG. 1, a large number of thin line parts 12h extending in the X direction are disposed with a gap therebetween in the Y direction. The thin line parts 12h are disposed between the two thick line parts 12g and between the thick line part 12g and a circumferential edge portion of the solar cell element 10. By a combination of the thick line part 12g and the thin line part 12h, the first electrode 11 achieves both current collection efficiency and light transmittance.

The first transparent electrode 13 is formed of a transparent conductive metal oxide such as indium tin oxide (ITO) or indium zinc oxide (IZO). A thickness of the first transparent electrode 13 is preferably 30 to 300 nm when a material thereof is ITO.

The intermediate electrode 15 is disposed in a middle portion of the solar cell element 10 in the S direction. As illustrated in FIG. 2, the intermediate electrode 15 includes an intermediate transparent electrode 16 and an intermediate passivation layer 17 in that order from a side in the +S direction to a side in the −S direction.

The intermediate transparent electrode 16 has a function of electrically connecting the top cell 20 and the bottom cell 25 while isolating them. The intermediate transparent electrode 16 has a function of guiding light that has not been absorbed by the top cell 20 to the bottom cell 25. Similarly to the first transparent electrode 13, a material of the intermediate transparent electrode 16 can be selected from transparent or translucent materials having conductivity. A thickness of the intermediate transparent electrode 16 is preferably 5 to 70 nm.

The intermediate passivation layer 17 preferably contains silicon oxide. The intermediate passivation layer 17 may be a uniform layer without openings or a discontinuous layer partially with openings. A thickness of the intermediate passivation layer 17 is preferably 1 to 20 nm when openings are not provided, and 10 to 1000 nm when openings are provided. A shape of the openings is a groove shape or a hole shape. The groove-shaped openings may be disposed at regular intervals or may be disposed at random intervals. The hole-shaped openings may be uniformly distributed or non-uniformly distributed.

The second electrode 19 is disposed at an end portion of the solar cell element 10 in the −S direction. The second electrode 19 is formed of a metal material having conductivity such as aluminum. The second electrode 19 covers the entire back surface of the solar cell element 10. The solar cell element 10 absorbs light incident from the first electrode 11, which is a surface thereof, by the photoactive layers 22 and 27. The solar cell element 10 reflects light that has not been absorbed by the photoactive layers 22 and 27 by the second electrode 19 on the back surface. When the light reflected by the second electrode 19 is absorbed by the photoactive layers 22 and 27, an amount of current generated in the solar cell element 10 increases. A thickness of the second electrode is preferably 20 to 300 nm.

The solar cell element 10 may utilize incident light from the second electrode 19 in addition to incident light from the first electrode 11. Similarly to the first electrode 11, the second electrode 19 in this case includes a metal electrode and a second transparent electrode. The metal electrode and the second transparent electrode are disposed in that order from a side in the −S direction to a side in the +S direction.

As illustrated in FIG. 1, the plurality of solar cell elements 10 are disposed to be aligned in the X direction and the Y direction. The plurality of solar cell elements 10 are electrically connected in series or in parallel. The plurality of solar cell elements 10 include a first solar cell element 10A and a second solar cell element 10B connected in series. In the example of FIG. 1, the first solar cell element 10A and the second solar cell element 10B are disposed to be aligned in the Y direction. The solar cell module 1 includes a connection member 30 that connects the first solar cell element 10A and the second solar cell element 10B.

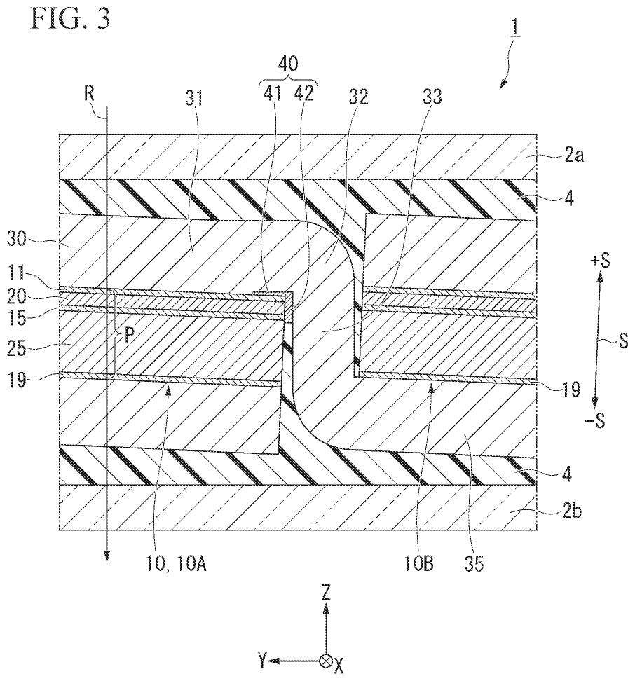

FIG. 3 is a cross-sectional view along line III-III of FIG. 1.

The connection member 30 is formed of a metal material having conductivity such as copper, aluminum, silver, or gold. The connection member 30 may be plated with chrome or a solder layer may be formed thereon. The connection member 30 is formed by bending a wire rod having a constant cross section. The connection member 30 connects the first electrode 11 of the first solar cell element 10A and the second electrode 19 of the second solar cell element 10B. The connection member 30 includes a first connection part 31, an intermediate part 33, and a second connection part 35. The first connection part 31, the intermediate part 33, and the second connection part 35 are all linear.

The first connection part 31 is disposed in the +S direction of the first electrode 11 along the first electrode 11 of the first solar cell element 10A. As illustrated in FIG. 1, the first connection part 31 covers substantially the entire thick line part 12g of the metal electrode 12 of the first electrode 11. A length and width of the first connection part 31 are the same as those of the thick line part 12g. The first connection part 31 is electrically connected to the thick line part 12g of the first electrode 11.

As illustrated in FIG. 3, the second connection part 35 is disposed in the −S direction of the second electrode 19 along the second electrode 19 of the second solar cell element 10B. As illustrated in FIG. 1, the second connection part 35 is disposed at a position in which the thick line part 12g of the first electrode 11 is projected onto the second electrode 19. A length and width of the second connection part 35 are the same as those of the thick line part 12g of the first electrode 11. The second connection part 35 is electrically connected to the second electrode 19.

As illustrated in FIG. 3, the intermediate part 33 is disposed between the first solar cell element 10A and the second solar cell element 10B. The intermediate part 33 is disposed parallel to the Z direction or the S direction. The intermediate part 33 is disposed away from first solar cell element 10A and second solar cell element 10B.

The solar cell module 1 includes a sealing material 4, a first transparent plate 2a, a second transparent plate 2b, and a frame 6 (see FIG. 1).

The sealing material 4 is formed of a transparent resin material having electrical insulating properties such as ethylene vinyl acetate (EVA). The sealing material 4 covers the entirety of the plurality of solar cell elements 10 including the first solar cell elements 10A and the second solar cell elements 10B, and the connection member 30.

The first transparent plate 2a is a transparent plate material such as glass. The first transparent plate 2a is disposed at an end portion of the solar cell module 1 in the +S direction. Light incident on the solar cell module 1 from the +S direction passes through the first transparent plate 2a and the sealing material 4 to be incident on the solar cell element 10.

The second transparent plate 2b is a transparent plate material such as glass. The second transparent plate 2b is disposed at an end portion of the solar cell module 1 in the −S direction. If the solar cell module 1 does not utilize incident light from the −S direction, the second transparent plate 2b may be omitted. In this case, the solar cell module 1 may include a non-transparent plate instead of the second transparent plate 2b.

As illustrated in FIG. 1, the frame 6 is disposed around the solar cell module 1 in the X direction and Y direction. The frame 6 is formed of a metal material such as aluminum. Entering of water, air, or the like into the inside of the solar cell module 1 is suppressed by the frame 6.

As illustrated in FIG. 3, the solar cell module 1 includes a shield member 40. The shield member 40 is formed of a resin material having electrical insulating properties such as ethylene vinyl acetate (EVA), polyolefin elastomer (POE), polyethylene terephthalate (PET), or ionomer. The shield member 40 is disposed between the first solar cell element 10A and the connection member 30. The shield member 40 is fixed in advance to a surface of the connection member 30. Thereby, handling of the shield member 40 is facilitated. The shield member 40 is fixed to the surface of the connection member 30 by, for example, thermally fusing the shield member 40 to the surface of the connection member 30, fixing it with an adhesive (for example, an epoxy-based adhesive, a urethane-based adhesive, or a two-liquid mixture) or a thermosetting resin, or the like.

The shield member 40 includes a first portion 41 and a second portion 42.

The first portion 41 is disposed at an end portion of the first electrode 11 on the second solar cell element 10B side (−Y direction) between the first electrode 11 of the first solar cell element 10A and the first connection part 31 of the connection member 30. The first electrode 11 and the first connection part 31 are electrically connected in a region in which the first portion 41 is not disposed, and electrically insulated in a region in which the first portion 41 is disposed.

The first connection part 31 of the connection member 30 is parallel to the first transparent plate 2a and the Y direction. Since the first solar cell element 10A disposed in the —Z direction of the first connection part 31 includes the first portion 41 at an end portion in the −Y direction, the first solar cell element 10A is inclined in the —Z direction toward the −Y direction. Of the incident light on the solar cell module 1, incident light R parallel to the Z direction has the highest frequency of incidence. When the first solar cell element 10A is parallel to the Y direction, an optical path length P of the incident light R inside the first solar cell element 10A is the smallest. When the first solar cell element 10A is inclined with respect to the Y direction as in the present embodiment, the optical path length P of the incident light R inside the first solar cell element 10A increases. Thereby, an absorption rate of the incident light R in the photoactive layers 22 and 27 increases, and a photocurrent generated in the solar cell module 1 increases.

The first connection part 31 of the connection member 30 is parallel to the Y direction, and the intermediate part 33 is parallel to the Z direction or the S direction. The connection member 30 includes a bent part 32 between the first connection part 31 and the intermediate part 33. The second portion 42 of the shield member 40 is disposed on an inner side (inner circumferential side) of the bent part 32 and at an end portion of the intermediate part 33 in the +S direction.

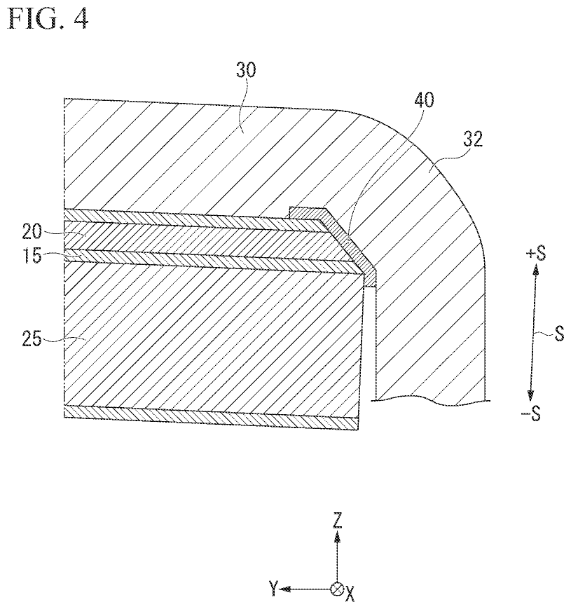

FIG. 4 is an enlarged view around the shield member 40. A mechanical strength of the perovskite semiconductor contained in the top cell 20 is weak. A thickness of the top cell 20 is about 500 nm, whereas a thickness of the connection member 30 is about 1000 μm. Therefore, when the bent part 32 is formed by bending the connection member 30, there is a likelihood that a part of the top cell 20 will be crushed on an inner side of the bent part 32. When the top cell 20 is crushed, short-circuiting between the connection member 30 and the intermediate electrode 15 or the bottom cell 25 occurs. Thereby, at least a part of power generation performance of the top cell 20 is not exhibited, and power generation performance of the solar cell module 1 deteriorates.

As illustrated in FIG. 3, the solar cell module 1 of the embodiment includes the shield member 40 made of an electrically insulating material. The first portion 41 of the shield member 40 is disposed between an end portion of the first electrode 11 of the first solar cell element 10A on the second solar cell element 10B side and the first connection part 31 of the connection member 30.

The first portion 41 is disposed at an end portion of the first connection part 31 on the bent part 32 side. Even if a part of the top cell 20 is crushed by the formation of the bent part 32, the first portion 41 is interposed between the connection member 30 and the bottom cell 25. Short-circuiting between the connection member 30 and the bottom cell 25 is suppressed by the first portion 41. Therefore, deterioration in power generation performance of the solar cell module 1 is curbed.

The connection member 30 includes the first connection part 31, the intermediate part 33, and a bent part 32. The first connection part 31 extends along the first electrode 11 of the first solar cell element 10A. The intermediate part 33 is disposed between the first solar cell element 10A and the second solar cell element 10B. The bent part 32 is disposed between the first connection part 31 and the intermediate part 33. The second portion 42 of the shield member 40 is disposed on an inner side of the bent part 32.

Even if a part of the top cell 20 is crushed by the formation of the bent part 32, the second portion 42 in addition to the first portion 41 is interposed between the connection member 30 and the bottom cell 25. Short-circuiting between the connection member 30 and the bottom cell 25 is easily suppressed, and deterioration in power generation performance of the solar cell module 1 is curbed.

An end portion of the second portion 42 in the −S direction is disposed in the −S direction from an end portion of the bottom cell 25 in the +S direction.

The end portion of the second portion 42 in the −S direction covers a side surface of the intermediate electrode 15 and a part of a side surface of the bottom cell 25. Even if a part of the top cell 20 is crushed, the second portion 42 can easily intervene between the connection member 30 and the bottom cell 25. Short-circuiting between the connection member 30 and the bottom cell 25 is suppressed, and deterioration in power generation performance of the solar cell module 1 is curbed. Since the shield member 40 is formed only at a portion in which a risk of short-circuiting is high, a risk of short-circuiting can be effectively suppressed. Since the shield member 40 covers only a part of the side surface of the bottom cell 25, a process of forming the shield member 40 is simple.

The shield member 40 is fixed to the connection member 30.

Thereby, handling of the shield member 40 is facilitated.

The solar cell module 1 includes the sealing material 4 and the first transparent plate 2a. The sealing material 4 is made of an electrically insulating material and covers the first solar cell element 10A, the second solar cell element 10B, and the connection member 30. The first transparent plate 2a is disposed at an end portion of the sealing material 4 in the +S direction.

The first solar cell element 10A, the second solar cell element 10B, and the connection member 30 are protected by the sealing material 4 and the first transparent plate 2a. Short-circuiting between members are suppressed by the sealing material 4. Light is incident on the solar cell element 10 from the +S direction of the solar cell module 1 through the first transparent plate 2a.

The solar cell module 1 includes the second transparent plate 2b disposed at an end portion of the sealing material 4 in the −S direction.

The first solar cell element 10A, the second solar cell element 10B, and the connection member 30 are protected by the second transparent plate 2b. Light is incident on the solar cell element 10 from the −S direction of the solar cell module 1 through the second transparent plate 2b.

The solar cell module 1 includes the frame 6 disposed around the first transparent plate 2a, the second transparent plate 2b, and the sealing material 4.

Entering of water, air, or the like into the inside of the solar cell module 1 is suppressed by the frame 6.

According to at least one embodiment described above, the solar cell module 1 includes the first solar cell element 10A and the second solar cell element 10B disposed to be aligned, the connection member 30, and the shield member 40. The connection member 30 electrically connects the first electrode 11 of the first solar cell element 10A and the second electrode 19 of the second solar cell element 10B. The first solar cell element 10A and the second solar cell element 10B each include the top cell 20 containing a perovskite semiconductor and the bottom cell 25 containing silicon. The top cell 20 and the bottom cell 25 are disposed to be aligned in the S direction of the first solar cell element 10A and the second solar cell element 10B to be electrically connected in series. The first electrode 11 is disposed at an end portion in the +S direction in which the top cell 20 is disposed in the S direction. The second electrode 19 is disposed at an end portion in the −S direction in which the bottom cell 25 is disposed in the S direction. The shield member 40 is made of an electrically insulating material, and is disposed between an end portion of the first electrode 11 of the first solar cell element 10A on the second solar cell element 10B side and the connection member 30. Thereby, deterioration in power generation performance of the solar cell module 1 can be curbed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar cell module comprising:
a first solar cell element and a second solar cell element disposed to be aligned; and
a connection member electrically connecting a first electrode of the first solar cell element and a second electrode of the second solar cell element, wherein
the first solar cell element and the second solar cell element each include a first cell containing a perovskite semiconductor and a second cell containing silicon,
the first cell and the second cell are disposed to be aligned in a thickness direction of the first solar cell element and the second solar cell element to be electrically connected in series,
the first electrode is disposed at an end portion in a first direction in which the first cell is disposed in the thickness direction,
the second electrode is disposed at an end portion in a second direction in which the second cell is disposed in the thickness direction, and
a shield member made of an electrically insulating material and disposed between an end portion of the first electrode of the first solar cell element on the second solar cell element side and the connection member is further provided.

2. The solar cell module according to claim 1, wherein an end portion of the shield member in the second direction is disposed in the second direction from an end portion of the second cell in the first direction.

3. The solar cell module according to claim 2, wherein the end portion of the shield member in the second direction covers only a part of a side surface of the second cell.

4. The solar cell module according to claim 1, wherein the shield member is fixed to the connection member.

5. The solar cell module according to claim 1, wherein
the connection member includes:
a first connection part extending along the first electrode of the first solar cell element;
an intermediate part disposed between the first solar cell element and the second solar cell element; and
a bent part disposed between the first connection part and the intermediate part, and
the shield member is disposed on an inner side of the bent part.

6. The solar cell module according to claim 1, further comprising:
a sealing material made of an electrically insulating material and covering the first solar cell element, the second solar cell element, and the connection member; and
a first transparent plate disposed at an end portion of the sealing material in the first direction.

7. The solar cell module according to claim 6, further comprising a second transparent plate disposed at an end portion of the sealing material in the second direction.

8. The solar cell module according to claim 7, further comprising a frame disposed around the first transparent plate, the second transparent plate, and the sealing material.
